(19) United States
(12) Patent Application Publication
(10) Pub. No.: US 2013/0207682 A1
(43) Pub. Date: Aug. 15, 2013

(54) PROBE PIN AND METHOD OF MANUFACTURING THE SAME

(71) Applicant: Hong Dae LEE, Seongnam (KR)

(72) Inventor: Hong Dae LEE, Seongnam (KR)

(73) Assignees: Toshiyuki NAKAMURA, Nakanoshi (JP); HUMAN LIGHT CO., LTD, Pyeongtack (KR); Chang Hoon LEE, Seongnam (KR)

(21) Appl. No.: 13/413,077

(22) Filed: Mar. 6, 2012

(30) Foreign Application Priority Data
Feb. 14, 2012 (KR) 10-2012-0014900

(51) Int. Cl. G01R 1/067; H01R 43/20

(52) U.S. Cl. 324/755.05; 29/876

(57) ABSTRACT

Disclosed are a spring-type probe pin having upper and lower contacts, and a manufacturing method thereof. The spring-type probe pin includes: cylindrical upper and lower sleeves having upper and lower grounded portions, respectively, in which one of the sleeves moves to be guided into the other; and a shock-absorbing operation unit provided between the upper and lower sleeves and containing a pair of shock-absorbing springs having a spiral spring form, which are connected to each other in such a manner that a turn of the upper shock-absorbing spring deviates from a turn of the lower shock-absorbing spring, in which the shock-absorbing operation unit performs an elastic shock-absorbing operation up to a position where the upper and lower shock-absorbing springs overlap each other. The cylindrical upper and lower sleeves and the shock-absorbing operation unit are integrally formed by using a press forming process.

### BACKGROUND OF THE INVENTION

1. Field of the Invention

The present invention relates to a spring-type probe pin having upper and lower contacts, and more particularly to a probe pin having upper and lower contacts which is integrally formed by punching and press-forming an elastic plate member, so that the probe pin can be manufactured at low cost with a high production yield. In the probe pin, upper and lower sleeves having upper and lower grounded portions, respectively are moved in a vertical direction. The probe pin can be realized in a compact body while maximizing the wire length of a shock-absorbing operation unit provided between the upper and lower sleeves and also maximizing the shock-absorbing stroke. The probe pin has good elastic force counteracting a pressure (load), good electrical characteristics, and excellent lasting durability.

2. Description of the Related Art

Generally, an electric or electronic part such as a test socket for testing a semiconductor element formed in a wafer or a semiconductor chip package uses a spring-type probe pin having a structure with upper and lower contacts.

There are many known forms of spring-type probe pins having upper and lower contacts. Korean patent registration numbers 10-1031634 and 10-82311 which were registered by the present applicant disclose such a spring-type probe pin having upper and lower contacts.

In the probe pin, a spring is connected between an upper grounded portion and a lower grounded portion. When a pressure (load) is applied to the probe pin in a vertical direction, it performs an elastic shock-absorbing operation.

However, a problem with the known conventional arts described above and the technologies that have been registered as patents by the present applicant is that when a pressure (load) is applied in the vertical direction, up-and-down shock-absorbing operations of the upper and lower grounded portions are not the same. Accordingly, they have poor reliability and durability and their electrical characteristics deteriorate over time.

Moreover, in the conventional arts described above and in the prior applications of the present applicant, the spring between the upper and lower grounded portions is a helical spring with a fixed radius. Accordingly, similarly to the operation principle of the helical spring, the spring performs a shock-absorbing operation by oscillating in the vertical direction by a distance (gap) of the turns of a spring wire.

That is, the spring between the upper and lower grounded portions performs a shock-absorbing operation by oscillating by distances corresponding to gaps between turns of a spring wire. Accordingly, when the manufactured probe pin has a very compact size (4 mm or smaller), it is difficult to secure a sufficient length of the spring and thus 1 mm or more of the shock-absorbing stroke may not be secured. Accordingly, the probe pin has very poor operability and durability.

Accordingly, it was very difficult to realize a very compact probe pin with a size of 4 mm or smaller in terms of durability and operability.

### SUMMARY OF THE INVENTION

Accordingly, the present invention has been made keeping in mind the above problems occurring in the related art, and an object thereof is to provide a probe pin which is integrally formed by using an elastic plate member as a raw material and using a press forming process as the manufacturing method, thereby being capable of reducing the manufacturing cost and improving the production yield.

An object of the present invention is to provide a probe pin including: upper and lower sleeves having upper and lower grounded portions, respectively which are installed such that one of the sleeves lies on top of the other and both of the sleeves move in the vertical direction; and a shock-absorbing operation unit provided between the upper and lower sleeves, in which the shock-absorbing operation unit includes a pair of shock-absorbing springs (upper and lower shock-absorbing springs) which have a form of a spiral spring and which are connected to each other, and the upper and lower shock-absorbing springs elastically move even up to a position where the upper and lower shock-absorbing springs overlap each other because turns of the upper and lower shock-absorbing springs deviate from each other. This configuration allows the size of the probe pin to be very compact (4 mm or smaller) while maximizing the wire length of the shock-absorbing operation unit and maximizing the shock-absorbing stroke. Moreover, the probe pin has good elastic operation force against a pressure (load) and good electrical characteristics. Most of all, the probe pin has long durability.

In the probe pin of the present invention, the upper and lower sleeves respectively having the upper and lower grounded portions may be installed to overlap each other and to constantly move in a vertical direction. Moreover, the shock-absorbing operation unit may be connected between the upper and lower sleeves using a structure in which a plurality of shock-absorbing springs are connected. Accordingly, the size of the probe pin can be made compact (4 mm or larger) while maximizing the wire length of the shock-absorbing operation unit and the shock-absorbing stroke. Moreover, the probe pin has good elastic force against the pressure (load) and good electrical characteristics. Most of all, the probe pin has long durability.

In order to achieve the object of the invention, there is provided a probe pin which is integrally formed using a press forming method in which cylindrical upper and lower sleeves respectively having upper and lower grounded portions are configured to overlap and move in a vertical direction, and a shock-absorbing operation unit is formed between the upper and lower sleeves and includes at least one pair of shock-absorbing springs (upper and lower shock-absorbing springs) which are wound like a spiral spring form and connected in the vertical direction. In the probe pin, turns of the upper and lower shock-absorbing springs deviate from each other so that the shock-absorbing operation is provided up to the position where the upper and lower shock-absorbing springs overlap.

The upper and lower shock-absorbing springs of the shock-absorbing operation unit are connected to the upper and lower sleeves. Also, left and right extensions, which extend to left and right sides from a central axis and are formed to continuously extend to form a zigzag shape by a punching process, are wound about the central axis to form a spiral spring form. Additionally, the upper shock-absorbing spring and the lower shock-absorbing spring are positioned such that their turns deviate from each other, so that the elastic shock-absorbing operation is exerted up to the position where the upper and lower shock-absorbing springs overlap.

According to the invention, the lower sleeve is guided and inserted into the upper sleeve so that the upper and lower sleeves are superimposed. The upper sleeve is bent inwards at a midway position to form a stopper which stops the shock-absorbing stroke of the lower sleeve.

In order to achieve the object of the invention, the present invention provides a method of manufacturing a probe pin including: punching an elastic plate member to form a punched body having a planar shape which is used to form upper and lower grounded portions, upper and lower sleeves, and a shock-absorbing operation unit of the probe pin, the shock-absorbing operation unit being provided between the upper and lower sleeves; forming upper and lower shock-absorbing springs in order to form the shock-absorbing operation unit by bending left and right extensions of the punched body, which continuously extend in a zigzag form to connect the upper and lower sleeves to each other, inwards about a central axis to form a spiral spring shape, in which turns of the upper and lower shock-absorbing springs deviate from each other so that a shock-absorbing operation is performed such that the upper and lower shock-absorbing springs overlap each other; forming the lower sleeve by bending a punched body which forms the lower sleeve so as to partially overlap the shock-absorbing operation unit and then by bending both ends of the punched body toward the outside of the shock-absorbing operation unit; and forming the upper sleeve by bending the lower sleeve and the shock-absorbing operation unit into a form that partially overlaps a punched body which forms the upper sleeve and then by bending both ends of the punched body toward the outside of the lower sleeve.

In order to achieve the object of the invention, there is provided a probe pin, in which cylindrical upper and lower sleeves respectively having upper and lower grounded portions are installed to overlap each other so that the upper and lower sleeves can move in the vertical direction, a shock-absorbing operation unit is formed between the upper and lower sleeves and includes one or more shock-absorbing springs which are spirally wound and connected in series in the vertical direction, and the shock-absorbing springs of the shock-absorbing operation unit are provided below the upper sleeve and above the lower sleeve in a manner such that at least one extension having an inverted C (or “>”) shape is wound spirally and integrally formed by a press forming process.

According to the present invention, the probe pin is integrally formed by using a press forming process as the manufacturing method and using an elastic plate member as a raw material, which reduces the manufacturing cost and improves the production yield.

The probe pin of the present invention includes upper and lower sleeves respectively having upper and lower grounded portions where the sleeves are provided such that one of the sleeves overlaps the other sleeve and the sleeves constantly move in the vertical direction. Accordingly, the probe pin can be made compact while maximizing the wire length of the spring-type shock-absorbing operation unit provided between the upper and lower sleeves and also maximizing the shock-absorbing stroke. Moreover, the probe pin has a good elastic force which counteracts the pressure (load) and good electrical characteristics. Most of all, the probe pin has long durability. The shock-absorbing operation unit includes a pair of shock-absorbing springs (upper and lower shock-absorbing springs), each having a spiral spring form. Moreover, the spring turns of the upper and lower shock-absorbing springs deviate from each other so that a shock-absorbing operation is exerted up to a position where the upper and lower shock-absorbing springs overlap each other. Accordingly, the wire length of the shock-absorbing operation unit and the shock-absorbing stroke are maximized, and therefore the probe pin with a very compact size (4 mm or smaller) can be realized. The shock-absorbing operation unit is configured with shock-absorbing springs that are spirally wound, which maximizes the wire length of the shock-absorbing operation unit and the shock-absorbing stroke, thereby enabling the probe pin to be realized in a compact size of 4 mm or larger.

The probe pin of the present invention can be realized in a compact size while maximizing the wire length of the shock-absorbing operation unit and the shock-absorbing stroke, and the probe pin has a good elastic force that counteracts the pressure (load) as well as good electrical characteristics and long-lasting durability thanks to the structure of the upper and lower sleeves, the structure which guides the upper and lower sleeves to constantly move and overlap, and the structure in which the shock-absorbing operation unit is installed inside the upper and lower sleeves.

### BRIEF DESCRIPTION OF THE DRAWINGS

The above and other objects, features and further advantages of the present invention will be more clearly understood from the following detailed description when taken in conjunction with the accompanying drawings, in which:

FIG. 1 is a front view illustrating a probe pin according to an embodiment of the present invention;

FIG. 2 a plan view of FIG. 1;

FIG. 3 is a cross-sectional view illustrating the probe pin according to the embodiment of the present invention;

FIG. 4 is a plan view illustrating a shock-absorbing operation unit of the probe pin according to the embodiment of the present application;

FIG. 5 is a plan view illustrating a punched body of the probe pin according to the embodiment of the present invention;

FIG. 6 is a process flow diagram illustrating the procedure of forming the probe pin of the present invention by using a punched body;

FIG. 7 is a process flow diagram illustrating the procedure of forming the shock-absorbing operation unit in more detail;

FIG. 8 is a front view illustrating an exploded state of a probe pin according to another embodiment of the present invention;

FIG. 9 is a cross-sectional view illustrating the probe pin of FIG. 8;

FIG. 10 is a cross-sectional view illustrating an exploded state of a probe pin according to a further embodiment of the present invention; and

FIG. 11 is a cross-sectional view illustrating the probe pin of FIG. 10.

### DETAILED DESCRIPTION OF THE INVENTION

Hereinbelow, preferred embodiments of the present invention will be described in detail with reference to the accompanying drawings.

An embodiment of a spring-type probe pin 100 having upper and lower contacts will be described. The spring-type probe pin 100 can be realized in a very compact size of 4 mm or smaller in the vertical direction.

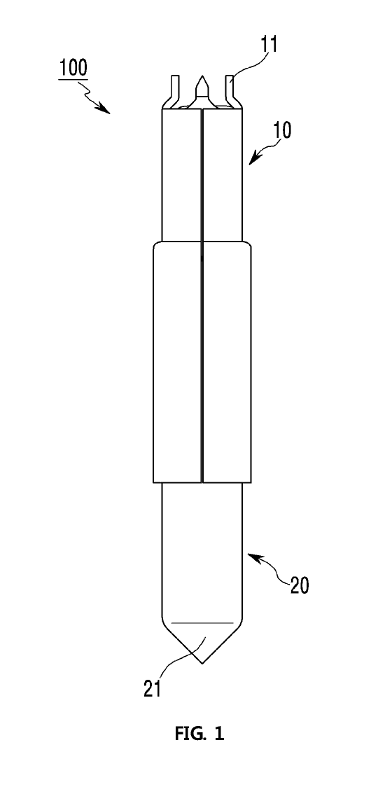

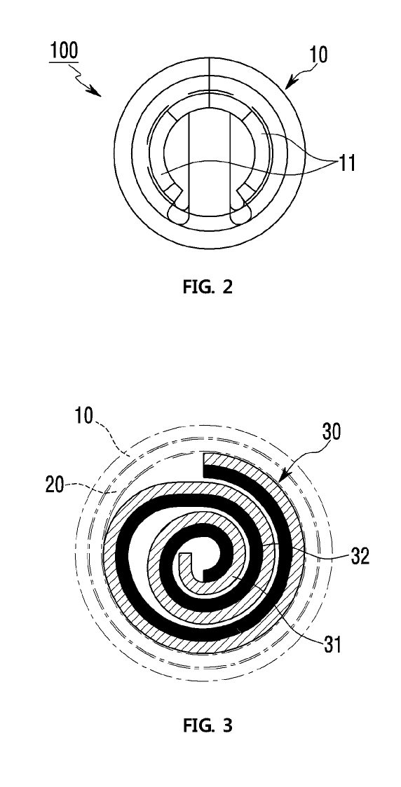

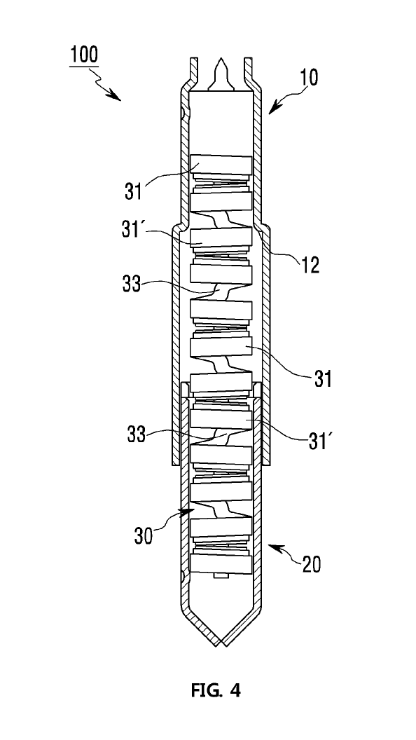

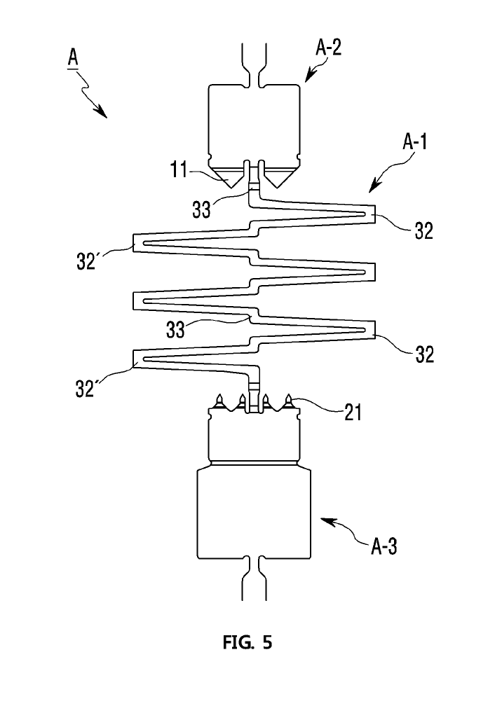

As illustrated in FIGS. 1 to 5, the spring-type probe pin 100 includes cylindrical upper and lower sleeves 10 and 20 respectively having upper and lower grounded portions 11 and 21. The upper sleeve 10 and the lower sleeve 20 partially overlap such that the lower sleeve 20 is provided inside the upper sleeve 10 at an overlapping portion.

A shock-absorbing operation unit 30 is provided between the upper and lower sleeves 10 and 20. The shock-absorbing operation unit 30 includes a pair of upper and lower shock-absorbing springs 31 and 31′ that are spiral in form and that are connected in series in the vertical direction in such a manner that the turns of the springs deviate from each other. In the shock-absorbing operation unit 30, each of the upper and lower shock-absorbing springs 31 and 31′ elastically moves up and down even up to the point of overlap of the upper and lower shock-absorbing springs 31 and 31′.

The upper and lower shock-absorbing springs 31 and 31′ of the shock-absorbing operation unit 30 are connected to the upper and lower sleeves 10 and 20, respectively. Left and right extensions 32 and 32′, each having a letter C shape (or “<” shape) or an inverted letter C shape (or “>” shape), are punched to be connected continuously in a zigzag form and to extend to the left and right sides from a central axis 33. The left and right extensions 32 and 32′ are wound like a spiral spring in which the upper shock-absorbing spring 31 and the lower shock-absorbing spring 31′ are positioned such that their spring turns deviate from each other. Such a configuration allows the upper and lower shock-absorbing springs 31 and 31′ to elastically move up and down even up to the overlapping position.

That is, the upper and lower shock-absorbing springs 31 and 31′ elastically move up and down not only in gaps between turns of the upper and lower shock-absorbing springs 31 and 31′ but also up to the overlapping position of the turns of the upper and lower shock-absorbing springs 31 and 31′.

The lower sleeve 20 vertically moves and is guided to be partially inserted into the upper sleeve 10. The upper sleeve 10 is bent at a midway position in the longitudinal direction so that the interior surface of the upper sleeve 10 is bent inwards. Accordingly, the bent portion serves as a stopper 12 that stops the stroke of the lower sleeve 20 during the shock-absorbing operation.

The probe pin 100 of the present invention is integrally formed by punching an elastic plate member and subjecting the punched piece to a press forming process.

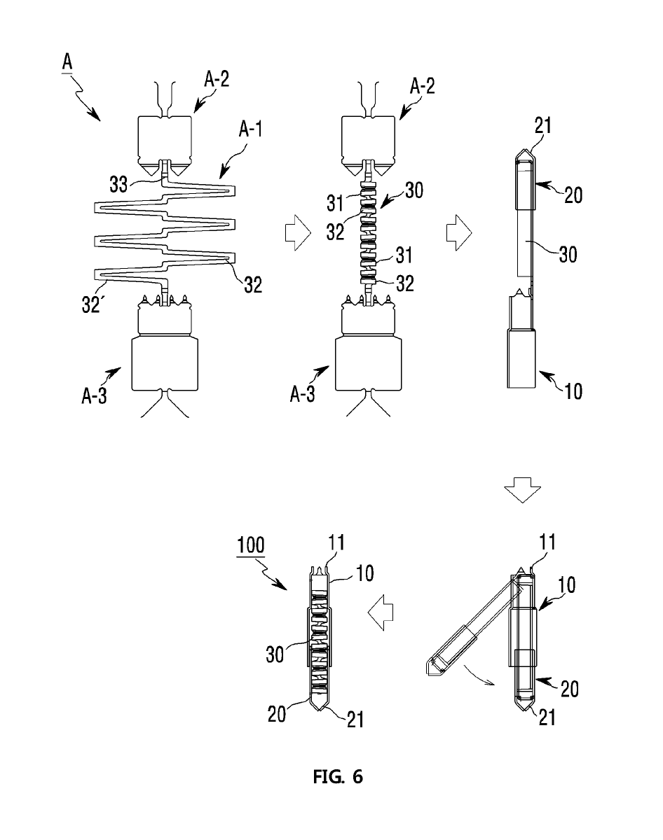

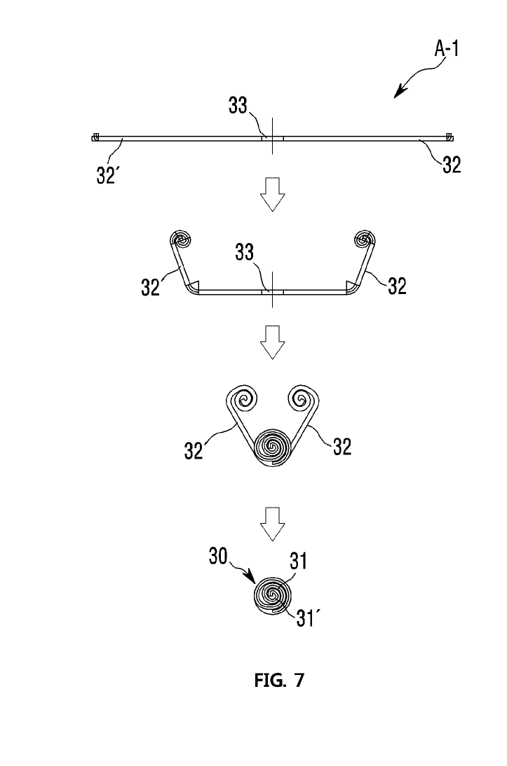

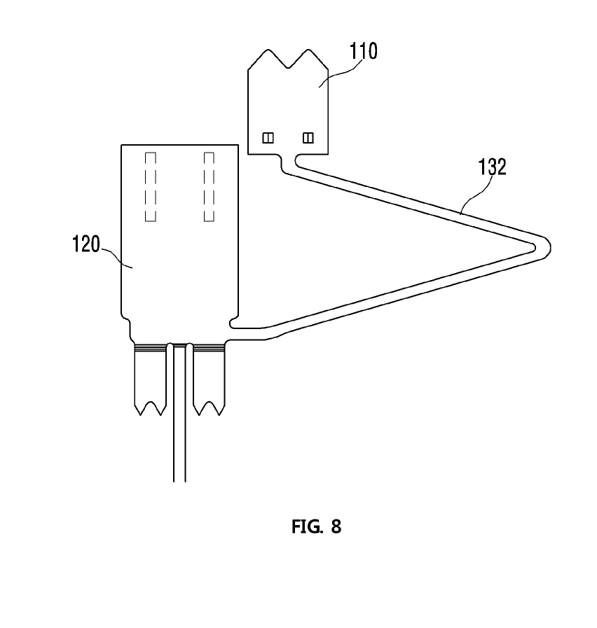

A method of manufacturing the probe pin according to the present invention is described below with reference to FIGS. 6 and 7.

First, a punched body forming step is performed. In the punched body forming step, a punched body A having a planar shape is formed. That is, an elastic plate member 1 is punched to form the punched body A of a probe pin 100 which is composed of upper and lower grounded portions 11 and 21, upper and lower sleeves 10 and 20, and a shock-absorbing operation unit 30 provided between the upper and lower sleeves 10 and 20.

A punched body A-1 which serves to form the shock-absorbing operation unit 30 is configured such that one or more left and right extensions 32 and 32′, each having a letter C shape (or “<” shape) or an inverted letter C shape (or “>” shape), are connected in zigzag form. The punched body A-1 is connected between the upper and lower sleeves 10 and 20.

The left and right extensions 32 and 32′ of the punched body A-1 which serves to form the shock-absorbing operation unit 30 are bent inwards (that is, toward a central axis 33) to be wound like a spiral spring form, so that at least one of the upper and lower shock-absorbing springs 31 and 31′ is formed. In this case, the upper and lower shock-absorbing springs 31 and 31′ are positioned to overlap each other in the vertical direction in such a manner that the spring turns of the upper and lower shock-absorbing springs deviate from each other. Therefore, the upper and lower shock-absorbing springs 31 and 31′ elastically move to overlap each other in the vertical direction, thereby performing the elastic shock-absorbing operation.

Next, a lower sleeve forming step is performed. In this step, a punched body A-2 which serves to form the lower sleeve 20 is bent so that the bent portion may overlap the shock-absorbing operation unit 30, and then both ends of the punched body A-2 are wound toward the outside of the shock-absorbing operation unit 30.

Both ends of the punched body A-2, which forms the lower sleeve 20, are partially wound and bent so that the bent portion overlaps the shock-absorbing operation unit.

In this state, the lower sleeve 20 and the shock-absorbing operation unit 30 are bent to partially overlap a punched body A-3 which serves to form the upper sleeve 10, and then both ends of the punched body A-3 are bent toward the outside of the lower sleeve 20, thereby forming the upper sleeve.

Both end portions of the punched body A-3 which forms the upper sleeve 10 are wound and bent. Moreover, the upper sleeve 10 is bent such that a midway position of the punched body A-3 is bent inwards to form the stopper 12 of the probe pin. Then, the lower sleeve 20 and the shock-absorbing operation unit 30 are bent to overlap.

In this way, the probe pin of the present invention is integrally formed by a press forming process as illustrated in FIGS. 1 to 4. Accordingly, it is possible to reduce the manufacturing cost and improve the productivity.

In the probe pin 100, the upper and lower grounded portions 11 and 21 are connected to external terminals (not illustrated) when the probe pin 100 is used. The upper and lower sleeves 10 and 20 move up and down by a certain distance in accordance with a pressure (load), and thus the shock-absorbing operation unit 30 performs the elastic shock-absorbing operation.

Specifically, the upper and lower sleeves 10 and 20 move in the vertical direction so that the lower sleeve 20 is guided and inserted into the upper sleeve 10. The shock-absorbing operation unit 30 is configured by connecting a pair of springs, i.e. upper and lower shock-absorbing springs 31 and 31′ that are wound like a spiral spring between the upper and lower sleeves 10 and 20. The upper and lower shock-absorbing springs 31 and 31′ are positioned such that the spring turn of the upper shock-absorbing spring 31 deviates from the spring turn of the lower shock-absorbing spring 31′. Accordingly, the shock-absorbing operation of the springs 31 and 31′ is performed not only in a gap between the upper and lower shock-absorbing springs 31 and 31′ but also up to the point where the upper and lower shock-absorbing springs 31 and 31′ overlap each other. Consequently, the probe pin can be realized in a small size (4 mm or smaller) while maximizing the wire length of the shock-absorbing operation unit 30 and hence the shock-absorbing stroke. Moreover, elastic force of the prove pin is excellent in counteracting the pressure (load) and electrical characteristics. Most of all, even when the probe pin 100 is manufactured in a vey compact size of 4 mm or smaller, it has a vertical stroke length of 1 mm or longer and can be used for a long period of time (the equivalent of 300,000 strokes).

Accordingly, the probe pin 100 according to the embodiment described above includes a structure composed of upper and lower sleeve structures, a structure in which the lower sleeve is guided inside the upper sleeve, and the shock-absorbing operation unit having a spiral spring form which is provided in the upper and the lower sleeves. The probe pin 100 is manufactured to have a very small size while maximizing the length of the shock-absorbing operation unit and the length of the shock-absorbing stroke. The elastic force of the probe pin 100 is excellent in counteracting the pressure (load) and, most of all, the probe pin 100 has excellent durability.

Next, an embodiment, in which a probe pin of a spring type having upper and lower contacts can be manufactured in a compact size (vertical size) of 4 mm or larger, will be described.

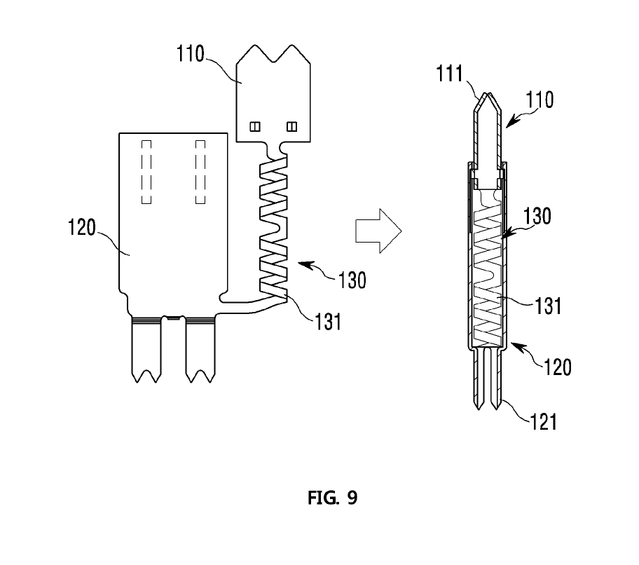

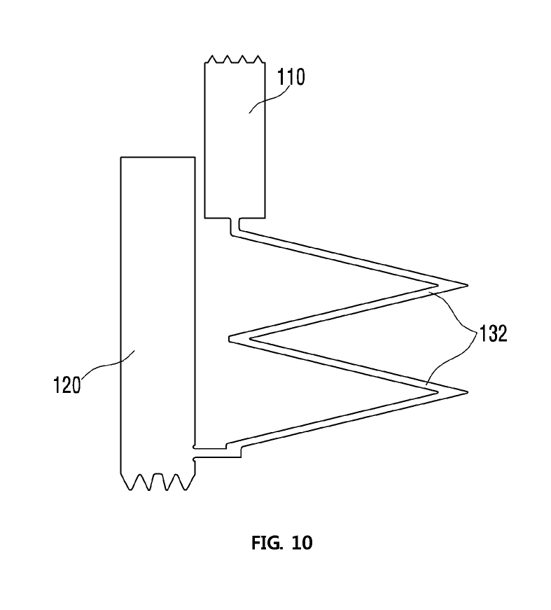

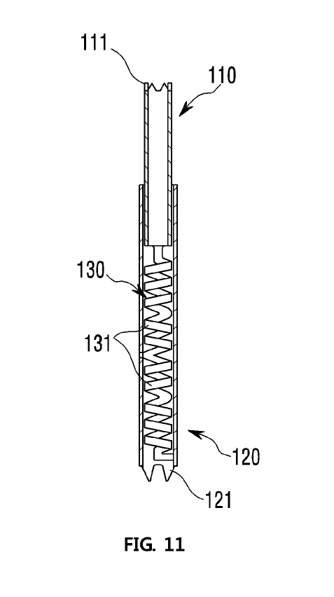

As illustrated in FIGS. 8 to 11, cylindrical upper and lower sleeves 110 and 120 having upper and lower grounded portions 111 and 121, respectively are configured such that one of the sleeves is inserted inside the other and hence one of the sleeves lies on top of the other. Between the upper and lower sleeves 110 and 120, a shock-absorbing operation unit 130 is provided. The shock-absorbing operation unit 130 is integrally formed by a press forming process so that at least one shock-absorbing spring 131 of a spiral spring type is provided or two or more shock-absorbing springs of a spiral spring type are connected in series in the vertical direction.

The upper and lower sleeves 110 and 120 are formed by bending a plate member, and the shock-absorbing operation unit 130 is formed by connecting at least one extension 132 having an inverted letter C shape or a “>” shape toward a lower portion of the upper sleeve 110 and an upper portion of the lower sleeve 120, and spirally winding the extensions 132 to form the shock-absorbing spring 131.

According to this embodiment, like the other embodiments described above, the upper and lower sleeves 110 and 120 having the upper and lower grounded portions 111 and 112, respectively are moved in the vertical direction, and the shock-absorbing spring 132 installed inside the upper and lower sleeves performs the elastic shock-absorbing operation. Accordingly, the probe pin can be realized in a compact size (4 mm or larger) while maximizing the wire length of the shock-absorbing operation unit 30 and the length of the shock-absorbing stroke, and moreover the probe pin has long-lasting durability and the elastic force that counteracts the pressure (load) is good.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A probe pin of a spring-type having upper and lower contacts and performing an elastic shock-absorbing operation against a pressure (load) applied in a vertical direction, the spring-type probe pin comprising:
cylindrical upper and lower sleeves having upper and lower grounded portions, respectively, the sleeves moving in the vertical direction such that one of the sleeves moves to be guided into the other and hence one of the sleeves lies on top of the other; and
a shock-absorbing operation unit provided between the upper and lower sleeves and including at least a pair of upper and lower shock-absorbing springs having a spiral spring form, which are connected to each other in the vertical direction in such a manner that a turn of the upper shock-absorbing spring deviates from a turn of the lower shock-absorbing spring, the shock-absorbing operation unit performing an elastic shock-absorbing operation up to a position where the upper and lower shock-absorbing springs overlap each other, the cylindrical upper and lower sleeves and the shock-absorbing operation unit being integrally formed as a result of a press forming process.

2. The probe pin of a spring type according to claim 1,
wherein the upper and lower shock-absorbing springs of the shock-absorbing operation unit are connected to the upper and lower sleeves,
wherein left and right extensions having a letter C shape (“<” shape) or an inverted letter C shape (“>” shape) extend to left and right sides from a central axis to form a zigzag shape, formed by a punching method, and spirally wound about the central axis like a spiral spring, and
wherein the turn of the upper shock-absorbing spring deviates from the turn of the lower shock-absorbing spring so that an elastic shock-absorbing operation is exerted up to the position where the upper and lower shock-absorbing springs overlap each other.

3. The probe pin of a spring type according to claim 1,
wherein the lower sleeve is guided in the vertical direction to be inserted into the upper sleeve so that the upper sleeve lies on top of the lower sleeve,
wherein the upper sleeve is bent inward at a midway position thereof to form a stopper that stops a stroke of the lower sleeve that performs a shock-absorbing operation.

4. A method of manufacturing a probe pin of a spring type having upper and lower contacts, which absorbs a shock attributable to a pressure applied in a vertical direction by performing an elastic shock-absorbing operation, the method comprising:
punching an elastic plate member to form a punched body having a planar shape which is used to form upper and lower grounded portions, upper and lower sleeves, and a shock-absorbing operation unit of the probe pin, the shock-absorbing operation unit being provided between the upper and lower sleeves;
forming upper and lower shock-absorbing springs in order to form the shock-absorbing operation unit by bending left and right extensions of the punched body, which continuously extend in a zigzag form to connect the upper and lower sleeves to each other, inwards about a central axis to form a spiral spring shape, in which turns of the upper and lower shock-absorbing springs deviate from each other so that a shock-absorbing operation is performed in such a manner that the upper and lower shock-absorbing springs overlap each other;
forming the lower sleeve by bending a punched body, which serves to form the lower sleeve, into a form that partially overlaps the shock-absorbing operation unit, and then by bending both ends of the punched body toward the outside of the shock-absorbing operation unit; and
forming the upper sleeve by bending the lower sleeve and the shock-absorbing operation unit in a form that partially overlaps a punched body which forms the upper sleeve and then by bending both ends of the punched body which forms the upper sleeve toward the outside of the lower sleeve.

5. A probe pin of a spring type having upper and lower contacts which perform an elastic shock-absorbing operation which counteracts a pressure (load) applied in a vertical direction,
wherein cylindrical upper and lower sleeves respectively having upper and lower grounded portions are installed to overlap so that the upper and lower sleeves move in the vertical direction, and
wherein a shock-absorbing operation unit is formed between the upper and lower sleeves and configured by one or more shock-absorbing springs which are spirally wound and connected in series in the vertical direction, and
wherein the shock-absorbing springs of the shock-absorbing operation unit are provided below the upper sleeve and above the lower sleeve in a manner such that at least one extension having an inverted C (or “>”) shape is wound spirally and integrally formed by a press forming process.
